(19) United States
(12) Patent Application Publication
(10) Pub. No.: US 2025/0043162 A1
(43) Pub. Date: Feb. 6, 2025

(54) INKJET RESIN COMPOSITION AND DISPLAY DEVICE

(71) Applicants: SAMSUNG DISPLAY CO., LTD., YONGIN-SI (KR); DONGJIN SEMICHEM CO., LTD., Incheon (KR)

(72) Inventors: SANG-GU LEE, Yongin-si (KR); JUNHO CHOE, Hwaseong-si (KR); YE JIN KIM, Yongin-si (KR); ONNURI KIM, Yongin-si (KR); JINWUK KIM, Hwaseong-si (KR); YOUNG HYE SON, Yongin-si (KR); JUNYONG SONG, Hwaseong-si (KR); JIHO YUN, Hwaseong-si (KR)

(21) Appl. No.: 18/749,761

(22) Filed: Jun. 21, 2024

(30) Foreign Application Priority Data
Aug. 2, 2023 (KR) 10-2023-0100898

(51) Int. Cl. C09J 133/06; C09J 4/06; C09J 11/08; H05K 5/00; H05K 5/03

(52) U.S. Cl. CPC C09J 133/066; C09J 4/06; C09J 11/08; H05K 5/03; H05K 5/0086

(57) ABSTRACT

An inkjet resin composition includes about 20% to about 30% by weight of 2-ethylhexyl acrylate, about 20% to about 30% by weight of 4-hydroxybutyl acrylate, about 40% to about 50% by weight of isodecyl acrylate, about 1% to about 10% by weight of urethane acrylate, about 1% to about 5% by weight of an initiator, about 1% to about 5% by weight of a silane coupling agent, and about 0.05% to about 1% by weight of a surface flow control additive.

### CROSS-REFERENCE TO RELATED APPLICATION

This application claims priority under 35 U.S.C. § 119 to Korean Patent Application No. 10-2023-0100898, filed on Aug. 2, 2023, in the Korean Intellectual Property Office, the entire contents of which are incorporated by reference herein.

### TECHNICAL FIELD

The present invention relates to an inkjet resin composition and a display device made of the inkjet resin composition.

### DISCUSSION OF RELATED ART

As information technology (IT) develops, the importance of a display device as a connection medium between a user and information is being highlighted. For example, most current electronic devices need to transfer information to a user through a display device.

Recently, research and development of a foldable display device, a bendable display device, a rollable display device, etc., using a flexible display panel that can be bent or folded, are being conducted. Such display devices may be applied to various fields such as televisions and monitors as well as portable electronic devices and wearable devices.

The portable electronic devices such as smart phones and tablet PCs, which are becoming lighter and thinner for ease of portability, have been widely developed in various fields for ease of use.

The portable electronic devices may be foldable. A “foldable” electronic device with a flexible display provides a relatively larger screen than a general bar-type electronic device, making it easier to read. Furthermore, when the electronic device is folded, the size is reduced, making it convenient to carry. Therefore, it is in the limelight as an electronic device that satisfies consumers' tastes.

In the case of such a foldable display device used in the foldable electronic device, each stacked layer may satisfy folding characteristics to enable folding.

An adhesive layer may be positioned between two adjacent layers of the foldable display device to bond the two adjacent layers together.

### SUMMARY

Embodiments of the present invention relate to an inkjet resin composition having reduced volatility, enhanced ejection property, and reduced spreadability, and a display device made of the inkjet resin composition.

The inkjet resin composition according to an embodiment of the present invention includes about 20 to about 30 weight % of 2-ethylhexyl acrylate, about 20 to about 30 weight % of 4-hydroxybutyl acrylate, about 40 to about 50 weight % of isodecyl acrylate, about 1 to about 10 weight % of urethane acrylate, about 1 to about 5 weight % of initiator, about 1 to about 5 weight % of silane coupling agent, and about 0.05 to about 1 weight % of surface flow control additive.

The initiator may include at least one of 2,2-dimethoxy-1,2-diphenylethan-1-one or Bis(2,4,6-trimethylbenzoyl)-phenylphosphine oxide.

The surface flow control additive may include polydimethylsiloxan (PDMS).

The surface flow control additive may include a compound represented by Formula 2 below.

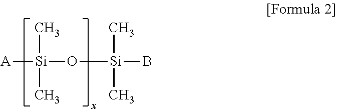

In this case, in Formula 2, A and B are each independently an alkyl or acrylate having 1 to 10 carbon atoms, and x is 1 to 10,000.

A content ratio of 2-ethylhexyl acrylate/4-hydroxybutyl acrylate may be about 0.67 to about 1.5.

A content ratio of the 2-ethylhexyl acrylate/(isodecyl acrylate+urethane acrylate) may be about 0.6 to about 0.73.

The inkjet resin composition may have a viscosity of about 50 cp or less at room temperature (25° C.).

A surface tension of the inkjet resin composition may be about 25 dyne/cm to about 31 dyne/cm.

The inkjet resin composition may have a modulus (G′) of about 0.3 MPa or less at −20° C. after UV curing.

The inkjet resin composition may have a modulus (G′) of about 0.01 MPa or more at 60° C. after UV curing.

According to an embodiment of the present invention, a foldable device includes a display panel, a cover window located on one side of the display panel, a battery located on an other side of the display panel, and an adhesive layer located between the display panel and the cover window, in which the adhesive layer includes an inkjet resin composition being cured, and the inkjet resin composition includes about 20 to about 30 weight percent of acrylate with a carbon number of 3 to 10, about 20 to about 30 weight percent of 4-hydroxybutyl acrylate, about 40 to about 50 weight percent of isodecyl acrylate, about 1 to about 10 weight percent of urethane acrylate, about 1 to about 5 weight percent of initiator, about 1 to about 5 weight percent of silane coupling agent, and about 0.05 to about 1 weight percent of surface flow control additive.

A glass transition temperature of the acrylate having 3 to 10 carbon atoms may be about −40° C. or less.

The surface flow control additive may include polydimethylsiloxan (PDMS).

A display device according to an embodiment of the present invention includes a display panel, a cover window positioned on one surface of the display panel, and an adhesive layer positioned between the display panel and the cover window, in which the adhesive layer includes an inkjet resin composition being cured. The inkjet resin composition includes about 20% to about 30% by weight of 2-ethylhexyl acrylate, about 20% to about 30% by weight of 4-hydroxybutyl acrylate, about 40% to about 50% by weight of isodecyl acrylate, about 1% to about 10% by weight of urethane acrylate, about 1% to about 5% by weight of initiator, about 1% to about 5% by weight of silane coupling agent, and about 0.05% to about 1% by weight of surface flow control additive.

An edge of the adhesive layer may be a curved surface.

A modulus (G′) of the adhesive layer at −20° C. may be about 0.3 MPa or less.

A modulus (G′) of the adhesive layer at 60° C. may be about 0.01 MPa or more.

The display device may be foldable.

The cover window may have a thickness of about 100 μm or less.

The adhesive layer may directly contact the cover window.

According to embodiments of the present invention, an inkjet resin composition having reduced volatility, enhanced ejection property, and reduced spreadability, and a display device made of the inkjet resin composition are provided.

### BRIEF DESCRIPTION OF THE DRAWINGS

Embodiments of the present invention will be more clearly understood from the following detailed description taken in conjunction with the accompanying drawings in which:

FIG. 1 schematically illustrates a cross-section of a display device according to an embodiment of the present invention;

FIG. 2 is an image of a defect in which craters are formed on the surface after the inkjet resin composition is ejected and cured when the surface flow control additive is not included;

FIG. 3 shows an unfilled crater;

FIG. 4 shows a half-filled crater;

FIG. 5 is a diagram showing the glass transition temperature according to the carbon number of the acrylic ester monomer;

FIG. 6 is a cross-sectional view of a display device according to an embodiment of the present invention; and

FIG. 7 schematically illustrates a foldable display device according to an embodiment of the present invention.

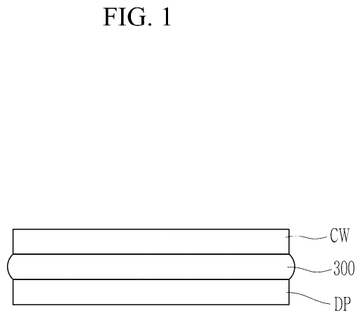

Since the drawings in FIGS. 1-7 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, with reference to the accompanying drawings, various embodiments of the present invention will be described in detail so that those skilled in the art can easily carry out the present invention.

The present invention may be embodied in many different forms and is not limited to the embodiments set forth herein.

To clearly describe the present invention, parts irrelevant to the description are omitted, and the same reference numerals indicate the same or similar components throughout the specification.

When a part such as a layer, film, region, or plate is said to be “above” or “on” another part, this includes not only the case where it is “directly on” the other part, but also the case where an intervening part exists in the middle thereof.

Conversely, when a part is said to be “directly on” another part, it means that there is no other part in between.

It will be understood that, being “above” or “on” a reference part means being located above or below the reference part, and does not necessarily mean being located “above” or “on” it in the opposite direction of gravity. It will be understood that the spatially relative terms are intended to encompass different orientations of the device in use or in operation, in addition to the orientation depicted in the figures.

Throughout the specification, when a certain component is said to “include”, it means that it may further include the stated other components but not to exclude any other components unless otherwise stated.

Throughout the specification, when reference is made to a “planar image”, it means when the target part is viewed from above, and when reference is made to a “cross-sectional image”, it means when a cross-section of the target part cut vertically is viewed from the side.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Hereinafter, an inkjet resin composition according to an embodiment of the present invention and a display device including the same will be described in detail with reference to drawings.

FIG. 1 schematically illustrates a cross-section of a display device according to an embodiment of the present invention.

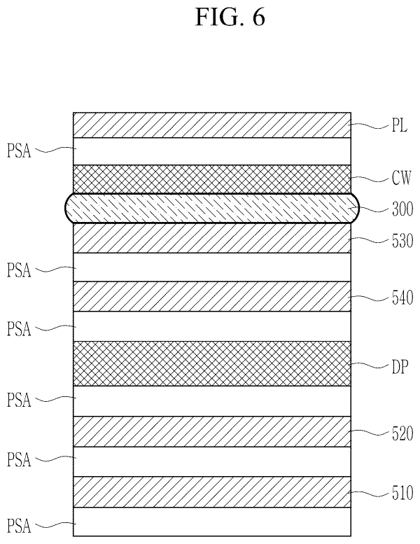

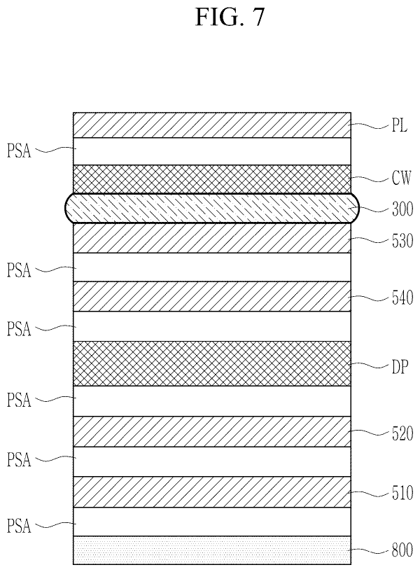

Referring to FIG. 1, the display device according to an embodiment of the present invention includes a display panel DP, a cover window CW positioned on the display panel DP, and a resin positioned between the display panel DP and the cover window CW. An adhesive layer 300 is included as the resin positioned between the display panel DP and the cover window CW. For example, the adhesive layer 300 may be interposed between the display panel DP and the cover window CW, so that the display panel DP and the cover window CW may be bonded to each other by the adhesive layer 300. For example, the adhesive layer 300 may directly contact the cover window CW. However, the adhesive layer 300 may not directly contact the display panel DP, and some films (see FIGS. 6 and 7) may be interposed therebetween.

The resin adhesive layer 300 may be formed through UV curing after applying an inkjet resin through an inkjet process.

As shown in FIG. 1, the inkjet resin composition according to an embodiment of the present invention may be a composition for forming the resin adhesive layer 300 between the cover window CW and the display panel DP.

The display device according to an embodiment of the present invention may be a foldable display device that can be folded and unfolded.

In a foldable display device, each layer can be bonded with a pressure-sensitive adhesive film. However, the pressure-sensitive adhesive film is expensive and has a problem in that slime is generated during processing and punching for adhesion.

In the display device according to an embodiment of the present invention, a portion of the adhesive layer of the foldable display device is formed of inkjet optically clear resin (OCR) using an inkjet resin composition.

To use the inkjet resin composition as an adhesive layer, the inkjet resin composition may have low viscosity to enable the jetting process, and may have high adhesive strength and low modulus after curing. When the inkjet resin composition has high adhesion strength, the adhesive layer formed may securely bond two adjacent layers to each other. The modulus described here is Young's modulus, which is also known as tensile modulus, elastic modulus or traction modulus.

Since slippage occurs during folding in a foldable display, an inkjet resin composition for forming an adhesive layer requires a low modulus capable of folding and excellent ejection properties for performing a jetting process. When the inkjet resin composition has low viscosity, it may allow the inkjet resin composition to have better flow and easier to be transferred onto the substrate or onto the layer to be bonded, and thus, the inkjet resin composition may have excellent ejection properties for performing a jetting process.

The present invention relates to an inkjet resin composition satisfying these characteristics and a display device including the same.

The inkjet resin composition according an embodiment of the present invention may include about 20 to about 30 weight % of 2-ethylhexyl acrylate, about 20 to about 30 weight % of 4-hydroxybutyl acrylate, about 40 to about 50 weight % of isodecyl acrylate, about 1 to about 10 weight % of urethane acrylate, about 1 to about 5 weight % of an initiator, about 1 to about 5 weight % of a silane coupling agent, and about 0.05 to about 1 weight % of a surface flowability control additive.

The initiator may include at least one of 2,2-dimethoxy-1,2-diphenylethan-1-one (Irgacure 651) or bis(2,4,6-trimethylbenzoyl)-phenylphosphine oxide (Irgacure 819). For example, 2,2-dimethoxy-1,2-diphenylethan-1-one (Irgacure 651) and/or bis(2,4,6-trimethylbenzoyl)-phenylphosphine oxide (Irgacure 819) are photoinitiators used to initialize the radical polymerization of the acrylate monomers to form acrylate polymers.

The surface flow control additive may include polydimethylsiloxan (PDMS). The surface control additive may be capable of mitigating surface energy gradients present within a liquid film immediately after application, and thus it may enhance flow, prevent retraction, minimize cratering, enable better surface leveling.

PDMS may be a compound represented by Formula 1 below, or may have a structure in which a methyl group is substituted with other group(s) as another compound, such as a compound represented by Formula 2 below.

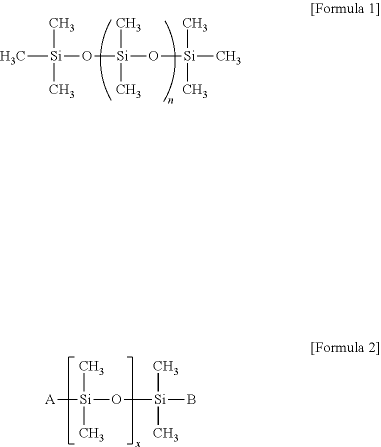

A and B in Formula 2 may each independently be an alkyl or acrylate having 1 to 10 carbon atoms.

In Formula 1 and Formula 2, x and n may be 1 to 10,000.

In the inkjet resin composition according to an embodiment of the present invention, the content ratio (2-EHA/4-HBA) of 2-ethylhexyl acrylate and 4-hydroxybutyl acrylate may be about 0.5 to about 1.5.

When the 2-EHA/4-HBA content is about 0.5 or less, low-temperature reliability may be reduced, and when the content is about 1.5 or more, volatility may not be sufficiently reduced. In an embodiment of the present invention, the content ratio (2-EHA/4-HBA) of 2-ethylhexyl acrylate and 4-hydroxybutyl acrylate of the inkjet resin composition may be about 0.67 to about 1.5.

The content ratio of 2-ethylhexyl acrylate/(isodecyl acrylate+urethane acrylate) in the inkjet resin composition according to an embodiment of the present invention may be about 0.6 to about 1.

When 2-ethylhexyl acrylate/(isodecyl acrylate+urethane acrylate) is about 0.6 or less, low-temperature reliability may decrease, and when about 1 or more, volatility may not sufficiently decrease. In an embodiment of the present invention, the content ratio of 2-ethylhexyl acrylate/(isodecyl acrylate+urethane acrylate) in the inkjet resin composition may be about 0.6 to about 0.73.

The inkjet resin composition according to an embodiment of the present invention may have a viscosity of about 50 cp or less at room temperature (25° C.). This viscosity is for good discharge.

The inkjet resin composition according to an embodiment of the present invention may have a modulus (G′) of about 0.3 MPa or less at−20° C. after UV curing and a modulus (G′) of about 0.01 MPa or more at 60° C. after UV curing.

The above described range for the modulus (G′) is a range for good folding at low and high temperatures when the inkjet resin composition is cured to form a resin adhesive layer.

The surface tension of the inkjet resin composition according to an embodiment of the present invention may be about 25 dyne/cm to about 31 dyne/cm.

Although described separately later, such surface tension is achieved by including a surface flow control additive, and through this, generation of craters during application may be prevented. For example, the surface flow control additive may include PDMS and/or a derivative of PDMS.

The inkjet resin composition according to an embodiment of the present invention may maintain good ejection property.

When the volatility is high, the discharge is not performed well over time, and even after the discharge, the resin is volatilized and spreads, and the shape is not maintained well.

The inkjet resin composition according to an embodiment of the present invention may reduce the amount of volatilization at the discharge temperature by reducing the content of 2-ethylhexyl acrylate, which is highly volatile, to induce a mixed vapor pressure lowering phenomenon. For example, decreasing the volatile component, for example, the volatile 2-ethylhexyl acrylate, and/or increasing the nonvolatile component in a volatile liquid result in a lowering of the liquid's vapor pressure.

To prevent the low-temperature folding characteristics from decreasing due to the decrease in the 2-ethylhexyl acrylate content, the low-temperature folding characteristics were maintained as the content of isodecyl acrylate was increased to about 40% by weight to about 50% by weight. In an embodiment of the present invention, the content of isodecyl acrylate of the inkjet resin composition may be increased from a range from about 10% by weight to about 20% by weight to a range from about 40% by weight to about 50% by weight. For example, the inkjet resin composition according to an embodiment of the present invention may reduce the amount of volatilization at the discharge temperature by reducing the content of 2-ethylhexyl acrylate, and increasing the content of isodecyl acrylate to 40% by weight to 50% by weight, so that a modulus (G′) of about 0.3 MPa or less at −20° C. after UV curing may be obtained, and a good low-temperature folding characteristics may then be maintained. Since a surface flow control additive such as PDMS is included, the surface tension of the inkjet resin composition is reduced to suppress surface defects.

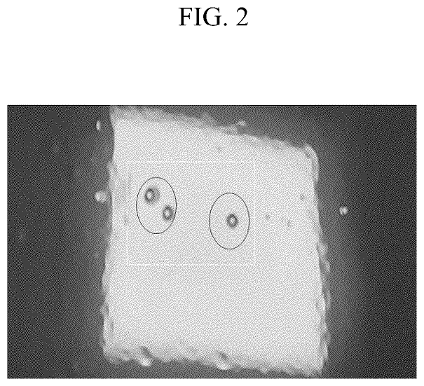

FIG. 2 is an image of a defect in which craters are formed on the surface after the inkjet resin composition is ejected, and cured when the surface flow control additive is not included.

As shown in the circled portion in FIG. 2, the inkjet resin composition may not be uniformly filled, and craters may be formed in an unfilled or half-filled form.

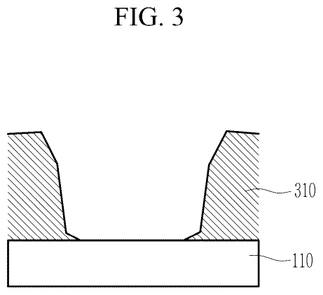

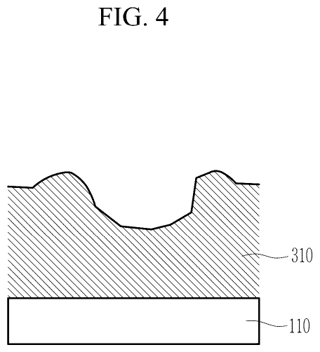

FIG. 3 shows a crater in an unfilled form, and FIG. 4 shows a half-filled crater.

In FIGS. 3 and 4, the inkjet resin composition 310 is positioned on the substrate 110, and the inkjet resin composition 310 does not spread uniformly, resulting in unfilled (FIG. 3) or half-filled (FIG. 4) craters.

Since the inkjet resin composition according to an embodiment of the present invention includes a surface flow control additive, the surface tension of the inkjet resin composition can be reduced (e.g., reduced to about 25 dyne/cm to about 31 dyne/cm) and the formation of craters on the surface can be prevented.

In this case, the content of the surface flow control additive may be about 0.05% by weight to about 1% by weight.

If the content of the surface flow control additive is less than about 0.05% by weight, the effect of reducing surface tension is poor, and craters may be formed on the coated surface.

When the content of the surface flow control additive exceeds about 1% by weight, the adhesive strength of the inkjet resin composition may decrease.

Table 1 below shows the degree of formation of craters while varying the content of the surface flow control additive.

A total of 20 applications were applied, and the number of applications in which craters were formed was measured and listed in Table 1.

TABLE 1

| surface flow control additive (%) | Crater |
|---|---|
| 0 | 14/20 |
| 0.03 | 3/20 |
| 0.05 | 0/20 |
| 0.1 | 0/20 |
| 1 | 0/20 |
| 1.5 | 0/20 |

Referring to Table 1, it can be seen that craters were formed during application when the content of the surface flow control additive is less than about 0.05%. For example, when the content of the surface flow control additive was 0%, 14 craters were formed, and when the content of the surface flow control additive was 0.03% by weight, 3 craters were formed.

Similarly, it was confirmed that no crater was formed during application when the content of the surface flow control additive was about 0.05% by weight or more.

Table 2 below shows the measurement of adhesiveness of inkjet resin compositions with different amounts of surface flow control additives.

TABLE 2

| surface flow control | | |
|---|---|---|
| additive (%) | maximum value [kgf] | average [kgf] |
| 0 | 1.28 | 1.21 |
| | 1.25 | 1.19 |
| 0.03 | 1.29 | 1.23 |
| | 1.23 | 1.23 |
| 0.05 | 1.19 | 1.16 |
| | 1.23 | 1.17 |
| 0.1 | 1.04 | 0.87 |
| | 0.90 | 0.78 |
| 1 | 0.23 | 0.19 |
| | 0.21 | 0.18 |
| 1.5 | 0.17 | 0.14 |
| | 0.14 | 0.12 |

Referring to Table 2, it was confirmed that the adhesive strength rapidly decreased when the content of the surface flow control additive exceeded about 1% by weight. For example, when the content of the surface flow control additive was 0.1% by weight, the average measured adhesiveness of the inkjet resin composition was 0.87 or 0.78 kilogram-force (kgf), and when the content of the surface flow control additive was 1% by weight, the average measured adhesiveness of the inkjet resin composition was 0.19 or 0.18 kgf.

It was confirmed that when the content of the surface flow control additive was about 0.05% to about 1% by weight, the adhesive force could be maintained while preventing the formation of craters, the amount of volatilization was induced to decrease by reducing the content of ethylhexyl acrylate and increasing the contents of 4-hydroxybutyl acrylate and isodecyl acrylate having low volatility.

Since the surface flow control additive is included, the formation of surface craters can be prevented, and an appropriate mixing ratio between monomers is selected to maintain physical properties at low temperatures.

An inkjet resin composition according to an embodiment of the present invention may include acrylate having 3 to 10 carbon atoms instead of 2-ethylhexyl acrylate. In an embodiment of the present invention, the inkjet resin composition may include about 20% to about 30% by weight of an acrylate having 3 to 10 carbon atoms.

The glass transition temperature of the acrylate containing 3 to 10 carbon atoms in the inkjet resin composition according to an embodiment of the present invention may be about −40° C. or less.

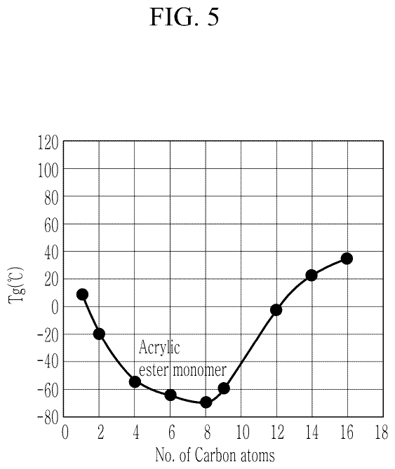

FIG. 5 is a diagram showing the glass transition temperature according to the carbon number of the acrylic ester monomer.

As shown in FIG. 5, it can be confirmed that the glass transition temperature is−40° C. or lower when the number of carbon atoms is 3 to 10.

Then, the effect of the inkjet resin composition according to an embodiment of the present invention will be described in comparison with the comparative example.

Table 3 below shows compositions of an inkjet resin composition having composition A according to an embodiment of the present invention, and an inkjet resin composition having composition B according to a comparative example.

TABLE 3

| | composition A | | composition B | |
|---|---|---|---|---|
| | compound | content (%) | compound | content (%) |
| monomer | 2-Ethylhexyl | 20-30 | 2-Ethylhexyl | 40-50 |
| | acrylate | | acrylate | |
| | 4- | 20-30 | 4- | 10-20 |
| | Hydroxybutyl | | Hydroxybutyl | |
| | acrylate | | acrylate | |
| | Isodecyl | 40-50 | Isodecyl | 10-20 |
| | acrylate | | acrylate | |
| oligomer | Urethane | 1-10 | Urethane | 20-30 |
| | acrylate | | acrylate | |
| initiator | Irgacure | 1-5 | Irgacure | 1-5 |
| | 651, 819 | | 651, 819 | |
| additive | Silane | 1-5 | Silane | 1-5 |
| | coupling agent | | coupling agent | |
| | PDMS | 0.05-1% | | |

As shown in Table 3, composition A according to an embodiment of the present invention has a content of 2-ethylhexyl acrylate lower than that of composition B, and a content of 4-hydroxybutyl acrylate and isodecyl acrylate higher than that of composition B. For example, the content of 2-ethylhexyl acrylate in composition A is 20-30% by weight, while the content of 2-ethylhexyl acrylate in composition B is 40-50% by weight. For example, the content of isodecyl acrylate in composition A is 40-50% by weight, while the content of isodecyl acrylate in composition B is 10-20% by weight. For example, the content of 4-hydroxybutyl acrylate in composition A is 20-30% by weight, while the content of 4-hydroxybutyl acrylate in composition B is 10-20% by weight.

Composition A further includes a surface flow control additive (PDMS). The volatilization characteristics of composition A and composition B were measured according to temperature, and are shown in Table 4.

TABLE 4

temperature(° C.)

| | | 35 | 40 | 45 | 55 |
|---|---|---|---|---|---|
| Weight | composition B | 1.12 | 2.94 | 5.56 | 10.56 |
| loss | | 0.98 | 2.79 | 5.50 | 11.64 |
| (%) | composition A | 0.33 | 0.77 | 1.38 | 3.54 |
| | | 0.46 | 0.79 | 1.45 | 3.97 |

Referring to Table 4, it can be seen that composition A according to an embodiment of the present invention has less volatilization than composition B. For example, at 55° C., the weight loss of composition A measured was 3.54% or 3.97%, while the weight loss of composition B measured was 10.56% or 11.64%.

It was confirmed that composition A according to an embodiment of the present invention had excellent ejection characteristics due to reduced volatility.

Table 5 below shows the results of evaluation of dormancy during ejection and evaluation of volatility after ejection for composition B.

Referring to Table 5, in the case of composition B, discharge defects appeared after 3 minutes, and it was confirmed that the discharged resin volatilized and spread. The evaluation results are shown.

Referring to Table 6, in the case of composition A according to an embodiment of the present invention, it was confirmed that no discharge defect appeared even after 15 minutes of discharge, and the discharged resin did not volatilize or spread even after 10 minutes.

When comparing the results of Table 5 and Table 6, it can be seen that composition A according to the present example has excellent ejection properties and low spreadability even after the lapse of time.

For composition A and composition B, the rate of occurrence of crater defects during ejection was measured and is shown in Table 7.

TABLE 7

| composition | Crater inferiority rate |
|---|---|
| composition B | 6.7% (10 F/150) |
| composition A | 0% (0 F/100) |

As can be seen in Table 7, composition A according to an embodiment of the present invention did not form a crater even once in 100 experiments, but composition B had 10 craters in 150 experiments, showing a defect rate of 6.7%.

Since the inkjet resin composition according to an embodiment of the present invention has low volatility, excellent ejection properties, and low resin spread due to volatilization after ejection, and contains a surface property control agent, formation of craters can be prevented during application.

Then, the display device according to an embodiment of the present invention will be described below.

The display device according to an embodiment of the present invention may include an adhesive layer formed by applying and curing the inkjet resin composition between the display panel and the cover window.

Referring back to FIG. 1, the resin adhesive layer 300 according to an embodiment of the present invention may have a curved edge.

This is because the inkjet resin composition is manufactured in a liquid state through coating and curing processes, and as shown in FIG. 1, a curved slope is formed at the edge.

In the case of an adhesive layer not made of such an inkjet resin composition, a curved slope is not formed at the edge, which is different.

FIG. 1 schematically illustrates a cross-sectional structure of a display device, and FIG. 6 illustrates this in more detail.

FIG. 6 is a cross-sectional view of a display device according to an embodiment of the present invention.

Referring to FIG. 6, the display device according to an embodiment of the present invention includes a display panel DP, a first lower film 510 positioned under the display panel DP, and a second lower film 520 positioned between the first lower film 510 and the display panel DP. A second upper film 540, a first upper film 530, a cover window CW, and a protective film PL are sequentially located on the display panel DP.

An adhesive layer (PSA) may be positioned on each of these layers. For example, the adhesive layer (PSA) may be interposed between two adjacent layers of these layers. In an embodiment of the present invention, the adhesive layer (PSA) may be a pressure-sensitive adhesive film.

The resin adhesive layer 300 according to an embodiment of the present invention may be positioned between the cover window CW and the first upper film 530.

The resin adhesive layer 300 according to an embodiment of the present invention is formed through a process of applying and curing the inkjet resin composition according to an embodiment of the present invention, and as described in FIG. 1, the edge may be formed as a curved surface.

The display devices shown in FIGS. 1 and 6 may be foldable display devices. The cover window CW may have a thickness of about 100 um or less.

In FIGS. 1 and 6, the modulus (G′) of the resin adhesive layer 300 at −20° C. may be about 0.3 MPa or less, and the modulus (G′) at 60° C. may be about 0.01 MPa or more. For example, the inkjet resin composition according to an embodiment of the present invention may have a modulus (G′) of about 0.3 MPa or less at −20° C. after UV curing to form the resin adhesive layer 300 and a modulus (G′) of about 0.01 MPa or more at 60° C. after UV curing to form the resin adhesive layer 300.

These physical properties can be derived when the resin adhesive layer 300 has a composition as described above.

FIG. 7 schematically illustrates a foldable display device according to an embodiment of the present invention.

Referring to FIG. 7, the foldable display device according to an embodiment of the present invention may further include a battery 800 positioned under the display panel DP. For example, the battery 800 may be positioned under the first lower film 510.

The foldable display device according to an embodiment of the present invention may be a mobile device including the battery 800, and descriptions of other components are the same as those described above, and thus are omitted.

Although the embodiments of the present invention have been described in detail above, the present invention is not limited thereto, and various modifications and equivalent arrangements may be made therein without departing from the spirit and scope of the present invention as defined in the appended claims.

What is claimed is:

1. An inkjet resin composition, comprising:
about 20% to about 30% by weight of 2-ethylhexyl acrylate;
about 20% to about 30% by weight of 4-hydroxybutyl acrylate;
about 40% to about 50% by weight of isodecyl acrylate;
about 1% to about 10% by weight of urethane acrylate;
about 1% to about 5% by weight of an initiator;
about 1% to about 5% by weight of a silane coupling agent; and
about 0.05% by weight to about 1% by weight of a surface flow control additive.

2. The inkjet resin composition of claim 1, wherein
the initiator includes at least one of 2,2-dimethoxy-1,2-diphenylethan-1-one or bis(2,4,6-trimethylbenzoyl)-phenylphosphine oxide.

3. The inkjet resin composition of claim 1, wherein
the surface flow control additive includes polydimethylsiloxan (PDMS).

4. The inkjet resin composition of claim 1, wherein
the surface flow control additive includes a compound represented by Formula 2 below: 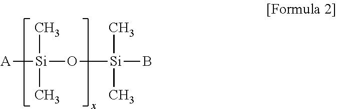
in Formula 2, A and B are each independently an alkyl or acrylate having 1 to 10 carbon atoms, and x is 1 to 10,000.

5. The inkjet resin composition of claim 1, wherein
a content ratio of 2-ethylhexyl acrylate/4-hydroxybutyl acrylate is about 0.67 to about 1.5.

6. The inkjet resin composition of claim 1, wherein
a content ratio of 2-ethylhexyl acrylate/(isodecyl acrylate+urethane acrylate) is about 0.6 to about 0.73.

7. The inkjet resin composition of claim 1, wherein
a viscosity of the inkjet resin composition at room temperature (25° C.) is about 50 cp or less.

8. The inkjet resin composition of claim 1, wherein
a surface tension of the inkjet resin composition is of about 25 dyne/cm to about 31 dyne/cm.

9. The inkjet resin composition of claim 1, wherein
the inkjet resin composition has a modulus (G′) of about 0.3 MPa or less at −20° C. after UV curing.

10. The inkjet resin composition of claim 1, wherein
the inkjet resin composition has a modulus (G′) of about 0.01 MPa or more at 60° C. after UV curing.

11. A foldable device, comprising:
a display panel;
a cover window positioned on one side of the display panel;
a battery positioned on an other side of the display panel; and
an adhesive layer positioned between the display panel and the cover window,
wherein the adhesive layer includes an inkjet resin composition being cured, and
the inkjet resin composition comprises:
about 20% to about 30% by weight of an acrylate having 3 to 10 carbon atoms;
about 20% to about 30% by weight of 4-hydroxybutyl acrylate;
about 40% to about 50% by weight of isodecyl acrylate;
about 1% to about 10% by weight of urethane acrylate;
about 1% to about 5% by weight of an initiator;
about 1% to about 5% by weight of a silane coupling agent; and
about 0.05% to about 1% by weight of a surface flow control additive.

12. The foldable device of claim 11, wherein a glass transition temperature of the acrylate having 3 to 10 carbon atoms is about −40° C. or less.

13. The foldable device of claim 11, wherein
the surface flow control additive includes polydimethylsiloxane (PDMS).

14. A display device, comprising:
a display panel;
a cover window positioned on one side of the display panel; and
an adhesive layer disposed between the display panel and the cover window,
wherein the adhesive layer includes an inkjet resin composition being cured, and
the inkjet resin composition comprises:
about 20% to about 30% by weight of 2-ethylhexyl acrylate;
about 20% to about 30% by weight of 4-hydroxybutyl acrylate;
about 40% to about 50% by weight of isodecyl acrylate;
about 1% to about 10% by weight of urethane acrylate;
about 1% to about 5% by weight of an initiator;
about 1% to about 5% by weight of a silane coupling agent; and
about 0.05% to about 1% by weight of a surface flow control additive.

15. The display device of claim 14, wherein
an edge of the adhesive layer is a curved surface.

16. The display device of claim 14, wherein
the adhesive layer has a modulus (G′) of about 0.3 MPa or less at −20° C.

17. The display device of claim 14, wherein
the adhesive layer has a modulus (G′) of about 0.01 MPa or more at 60° C.

18. The display device of claim 14, wherein
the display device is a foldable display device.

19. The display device of claim 14, wherein
the cover window has a thickness of about 100 μm or less.

20. The display device of claim 14, wherein
the adhesive layer directly contacts the cover window.
